(19) United States
(12) Patent Application Publication
(10) Pub. No.: US 2026/0114267 A1
(43) Pub. Date: Apr. 23, 2026

(54) CONDUCTIVE WIRES AND INTERCONNECT STRUCTURES AND INTEGRATED CIRCUIT DEVICES

(71) Applicant: SAMSUNG ELECTRONICS CO., LTD., Suwon-si (KR)

(72) Inventors: Keun Wook SHIN, Suwon-si (KR); Yu jin Han, Suwon-si (KR); Daejin YANG, Suwon-si (KR); GIYOUNG JO, Suwon-si (KR); JEONGYUB LEE, Suwon-si (KR); Tae Won JEONG, Suwon-si (KR)

(21) Appl. No.: 19/331,360

(22) Filed: Sep. 17, 2025

(30) Foreign Application Priority Data
Oct. 22, 2024 (KR) 10-2024-0144909

(51) Int. Cl. H01L 23/532; H01L 23/522

(52) U.S. Cl. CPC H10W 20/4446; H10W 20/425; H10W 20/42; H10W 20/48

(57) ABSTRACT

Disclosed are a conductive wire having a line width of less than about 10 nm and including a molybdenum-tantalum alloy and an integrated circuit device including the conductive wire.

### CROSS-REFERENCE TO RELATED APPLICATION

This application claims priority to Korean Patent Application No. 10-2024-0144909, filed on Oct. 22, 2024, and all the benefits accruing therefrom under 35 U.S.C. § 119, the content of which in its entirety is herein incorporated by reference.

### BACKGROUND

### 1. Field

The disclosure relates to conductive wires, interconnect structures including the conductive wires, and integrated circuit devices including interconnect structures.

### 2. Description of the Related Art

In order to provide highly integrated, high-performance integrated circuit devices, technologies for reducing the dimensions of unit devices that constitute integrated circuit devices are being studied, and accordingly, there is a demand to also reduce a line width of the wire that electrically connects the unit devices.

### SUMMARY

When a wire width of a wire is reduced below a certain range, the resistance of the wire may rapidly increase due to material limitations, which may deteriorate the electrical characteristics thereof.

An embodiment provides a conductive wire that may reduce or prevent degradation of electrical characteristics even at a reduced line width.

Another embodiment provides an interconnect structure including the conductive wire.

Another embodiment provides an integrated circuit device including the conductive wire or the interconnect structure.

According to an embodiment, a conductive wire includes a molybdenum-tantalum alloy, where the conductive wire has a line width of less than about 10 nanometers (nm).

In an embodiment, an aspect ratio of the conductive wire may be greater than or equal to about 3.

In an embodiment, an amount of tantalum included in the molybdenum-tantalum alloy may be less than about 50 at % based on a total number of atoms of molybdenum and tantalum.

In an embodiment, the molybdenum-tantalum alloy may be represented by Mo₁₋ₓTaₓ (0<x≤0.15).

In an embodiment, a change in resistivity of the conductive wire corresponding to a 10% decrease of the line width may be less than about twice.

In an embodiment, a resistivity of the conductive wire may be less than or equal to about 40μΩ·cm.

According to another embodiment, an interconnect structure includes a dielectric layer with a trench, and a conductive wire embedded in the trench, where the conductive wire includes a molybdenum-tantalum alloy and has a line width of less than about 10 nm and.

In an embodiment, an aspect ratio of the conductive wire may be greater than or equal to about 3.

In an embodiment, an amount of tantalum included in the molybdenum-tantalum alloy may be less than about 50 at % based on a total number of atoms of molybdenum and tantalum.

In an embodiment, the molybdenum-tantalum alloy may be represented by Mo₁₋ₓTaₓ (0<x≤0.15).

In an embodiment, a change in resistivity of the conductive wire corresponding to a 10% decrease of the line width may be less than about twice.

In an embodiment, a resistivity of the conductive wire may be less than or equal to about 40 μΩ·cm.

In an embodiment, the dielectric layer may include at least one selected from a metal oxide, a semi-metal oxide, a carbon-doped metal oxide, a carbon-doped semi-metal oxide, a metal carbide, a semi-metal carbide, a hydrogenated metal carbide, a hydrogenated semi-metal carbide, a metal nitride, a semi-metal nitride, a carbon-doped metal nitride, a carbon-doped semi-metal nitride, a metal oxynitride, a semi-metal oxynitride, a carbon-doped metal oxynitride or a carbon-doped metal oxynitride.

In an embodiment, the interconnect structure may further include an anti-scatter layer on an upper portion of the conductive wire.

In an embodiment, the interconnect structure may further include a barrier layer between the dielectric layer and the conductive wire.

In an embodiment, the dielectric layer may include a first dielectric layer and a second dielectric layer at different heights, a trench may be defined in each of the first dielectric layer and the second dielectric layer, and the conductive wire may include a first conductive wire embedded in the trench in the first dielectric layer and a second conductive wire embedded in the trench in the second dielectric layer.

In an embodiment, the interconnect structure may further include a via electrically connecting the first conductive wire and the second conductive wire to each other, where the via may include a conductor other than a molybdenum-tantalum alloy.

According to another embodiment, an integrated circuit device includes the conductive wire or the interconnect structure.

In an embodiment, the integrated circuit device may further include at least one selected from a transistor, a capacitor, a diode or a resistor, which are electrically connected to the conductive wire.

In an embodiment, in such an embodiment of a conductive wire, even when a width thereof is less than about 10 nm, a material limitation may be overcome and deterioration of electrical characteristics may be substantially reduced or effectively prevented.

### BRIEF DESCRIPTION OF THE DRAWINGS

FIG. 1 is a cross-sectional view showing an interconnect structure 30 according to an embodiment,

FIG. 2 is a cross-sectional view showing an interconnect structure according to another embodiment,

FIG. 3 is a cross-sectional view showing an interconnect structure according to another embodiment,

FIG. 4 is a cross-sectional view showing an interconnect structure according to another embodiment,

FIG. 5 is a plan view showing an integrated circuit device according to an embodiment,

FIG. 6 is a perspective view showing the integrated circuit device of FIG. 5,

FIG. 7 is a schematic view showing an embodiment of a transistor of the integrated circuit device of FIG. 5,

FIG. 8 is a block diagram showing an electronic device according to an embodiment, and

FIG. 9 is a graph showing the resistivity characteristics of the molybdenum-tantalum alloy wires according to Examples and the copper wire according to Reference Example.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

In the drawings, the thickness of layers, films, panels, regions, etc., are exaggerated for clarity. It will be understood that when an element such as a layer, film, region, or substrate is referred to as being “on” another element, it may be directly on the other element or intervening elements may also be present therebetween. In contrast, when an element is referred to as being “directly on” another element, there are no intervening elements present.

The drawings and description are to be regarded as illustrative in nature and not restrictive. Like reference numerals designate like elements throughout the specification.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The term “layer” includes a construction having a shape formed on a part of a region, in addition to a construction having a shape formed on an entire region.

As used herein, the term “the” or similar indicative terms correspond to both the singular form and the plural form. The steps of all methods described herein may be performed in any suitable order unless otherwise indicated herein or otherwise clearly contradicted by context.

Here, “combination thereof” refer to a mixture, a stacked structure, a composite, an alloy, or a blend of constituents.

Hereinafter, unless otherwise defined, “substantially” or “approximately” or “about” includes not only the stated value, but also the average within an allowable range of deviation, considering the error associated with the measurement and amount of the measurement. For example, “substantially” or “approximately” may mean within ±10%, ±5%, ±3%, or ±1% of the indicated value or within a standard deviation.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, “metal” is interpreted as a concept including metals and metalloids (semi-metals).

An example of a conductive wire according to an embodiment will hereinafter be described.

The conductive wire according to an embodiment may include any wire that transmits an electrical signal or includes an electrical connection, and for example, in an integrated circuit device, may include any wire that is electrically connects active devices to each other, passive devices to each other, and/or an active device and a passive device to each other.

The conductive wire may be a three-dimensional structure having a width, a length and a thickness, where the longitudinal direction of the conductive wire may be a direction in which electrons move and may be a direction perpendicular to the width direction and the thickness direction, respectively.

A line width of the conductive wire may be at the nanometer scale or on the nanoscale, for example, less than about 10 nanometers (nm), less than or equal to about 9 nm, less than or equal to about 8 nm, less than or equal to about 7 nm, less than or equal to about 6 nm, less than or equal to about 5 nm, less than or equal to about 4 nm, less than or equal to about 3 nm, greater than or equal to about 1 nm and less than 10 nm, about 1 nm to about 9 nm, about 1 nm to about 8 nm, about 1 nm to about 7 nm, about 1 nm to about 6 nm, about 1 nm to about 5 nm, about 1 nm to about 4 nm, or about 1 nm to about 3 nm.

The conductive wire may have a high aspect ratio, where the aspect ratio may be a ratio of height to width. The aspect ratio of the conductive wire may be greater than or equal to about 3, and within the range of about 3 to about 50, about 3 to about 45, about 3 to about 40, about 3 to about 35, about 3 to about 30, about 5 to about 50, about 5 to about 45, about 5 to about 40, about 5 to about 35, or about 5 to about 30. The conductive wire may be narrow and deep with a high aspect ratio in the above range.

In an embodiment, the conductive wire may include a molybdenum (Mo)-based multi-component alloy, for example a molybdenum (Mo)-based binary alloy or ternary alloy.

In an embodiment, for example, the conductive wire may include an alloy including molybdenum (Mo) and tantalum (Ta) (hereinafter referred to as a ‘molybdenum-tantalum alloy (Mo—Ta alloy)’). Unlike common bulk metals such as copper (Cu), the molybdenum-tantalum alloy may exhibit high reliability without a sharp increase in resistance in conductive wire with the aforementioned nanometer-level fine line widths.

Specifically, molybdenum (Mo) is a metal with relatively low resistivity and may be a base material for forming an alloy, and tantalum (Ta) is a metal with a relatively short electron mean free path (eMFP), which may effectively reduce electron scattering at the surface and grain boundaries in conductive wire with a fine line width of nanometers, thereby substantially reducing or effectively preventing a rapid increase in resistance. Accordingly, a product of the resistivity (bulk resistivity) and the electron mean free path of a metal may be an indicator for predicting the increase in resistivity in conductive wire with a fine line width at the nanometer scale, and the smaller the product of the resistivity (bulk resistivity) and the electron mean free path of a metal, the lower the rate of increase in resistivity of conductive wire with a fine line width may be expected to be.

In addition, the tantalum (Ta) is a metal with relatively high cohesive energy, which may reduce the drift of metal ions due to charging current or the diffusion or stress gradient of atoms due to heat, thereby increasing the reliability of conductive wire. In addition, these molybdenum (Mo) and tantalum (Ta) may form a uniform alloy by having a formation energy (Ex) less than 0 in all composition ratios of molybdenum (Mo) and tantalum (Ta).

For example, the bulk resistivity (ρ), electron mean free path (eMFP), their product, and cohesive energy (E_{CoE}) of molybdenum and tantalum are as shown in Table 1.

TABLE 1

| | ρ | eMFP | | E_{coh} |
|---|---|---|---|---|
| | (10⁻⁶ m) | (10⁻⁹ m) | ρ × eMFP 10⁻¹⁶ | (eV)** |
| Molybdenum (Mo)* | 5.34 | 12.2 | 5.99 | 6.12 |
| Tantalum (Ta) | 13.5 | 3.2 | 4.37 | 7.83 |
| Copper (Cu, Ref.)* | 1.678 | 39.9 | 6.7 | 3.43 |

*Daniel Gall, “Electron mean free path in elemental metals”, Journal of Applied Physics 119, 085101 2016.
**Sushant Kumar, Christian Multunas, Benjamin Defay, Daniel Gall, and Ravishankar Sundararaman, “Ultralow electron-surface scattering in nanoscale metals leveraging Fermi-surface anisotropy”, Physical Review Materials 6, 085002 2022.

For example, in a molybdenum-tantalum alloy, the product of resistivity (ρ) and electron mean free path (eMFP), cohesive energy (CoE), and alloy formation energy (E_{f}) according to the composition ratio of molybdenum (Mo) and tantalum (Ta) (more than 0 and less than 100 at %, respectively) are as shown in Table 2.

TABLE 2

| | | | E_{f} |
|---|---|---|---|
| | ρ × eMFP 10⁻¹⁶ | E_{coh} (eV) | (eV) |
| Molybdenum- | greater than about 4.37 | greater than about 6.12 | <0 |
| tantalum | and less than about 5.99 | and less than about | |
| alloy | | 7.83 | |
| Copper | 6.7 | 3.43 | — |
| (Cu, Ref.) | | | |

By effectively alloying molybdenum (Mo), which has a relatively low resistivity, with tantalum (Ta), which has a relatively short electron mean free path and relatively high cohesive energy, it may be applied to conductive wire with a fine line width of less than about 10 nm, thereby satisfying both conductivity and reliability. For example, in a conductive wire with a fine line width of less than about 10 nm, a change in resistivity of the conductive wire according to a 10% decrease in line width may be less than about twice. Within the above range, the change in resistivity of the conductive wire corresponding to a 10% decrease in line width may be about 1 to about 1.8 times, about 1 to about 1.6 times, or about 1 to about 1.4 times.

For example, in a conductive wire with a fine line width of less than about 10 nm, the resistivity of the conductive wire may be less than about 40 micro-ohm centimeters (μΩ·cm). Within the above range, the resistivity of the conductive wire may be less than or equal to about 38μΩ·cm, less than or equal to about 35μΩ·cm, less than or equal to about 30μΩ·cm, less than or equal to about 28μΩ·cm, less than or equal to about 26 μΩ·cm, or less than or equal to about 25 μΩ·cm, and within the above range about 2 μΩ·cm to about 40μΩ·cm, about 2μΩ·cm to about 38μΩ·cm, about 2μΩ·cm to about 35 μΩ·cm, about 2 μΩ·cm to about 30 μΩ·cm, about 2 μΩ·cm to about 28 μΩ·cm, about 2μΩ·cm to about 26μΩ·cm, about 2μΩ·cm to about 25μΩ·cm, about 5μΩ·cm to about 40 μΩ·cm, about 5 μΩ·cm to about to 38 μΩ·cm, about 5 μΩ·cm to about 35 μΩ·cm, about 5 μΩ·cm to about 30 μΩ·cm, about 5 μΩ·cm to about 28 μΩ·cm, about 5 μΩ·cm to about 26μΩ·cm, about 5μΩ·cm to about 25μΩ·cm, about 10μΩ·cm to about 40 μΩ·cm, about 10μΩ·cm to about 38μΩ·cm, about 10μΩ·cm to about 35μΩ·cm, about 10 μΩ·cm to about 30 μΩ·cm, about 10 μΩ·cm to about 28 μΩ·cm, about 10 μΩ·cm to about 26μΩ·cm, or about 10μΩ·cm to about 25μΩ·cm.

A composition ratio between molybdenum (Mo) and tantalum (Ta) in a molybdenum-tantalum alloy may be determined within a range that satisfies the aforementioned conductivity and reliability.

For example, in a molybdenum-tantalum alloy, molybdenum (Mo) may be included in greater amounts than tantalum (Ta), and tantalum (Ta) may be included in amounts less than about 50 at % based on the total number of atoms of molybdenum (Mo) and tantalum (Ta) included in the alloy. Within the above range, tantalum (Ta) may be included in an amount of greater than about 0 at % and less than or equal to about 45 atomic percent (at %), greater than about 0 at % and less than or equal to about 40 at %, greater than about 0 at % and less than or equal to about 35 at %, greater than about 0 at % and less than or equal to about 30 at %, greater than about 0 at % and less than or equal to about 25 at %, greater than about 0 at % and less than or equal to about 20 at %, greater than about 0 at % and less than or equal to about 15 at %, greater than about 0 at % and less than or equal to about 10 at %, about 2 at % to about 45 at %, about 2 at % to about 40 at %, about 2 at % to about 35 at %, about 2 at % to about 30 at %, about 2 at % to about 25 at %, about 2 at % to about 20 at %, about 2 at % to about 15 at %, or about 2 at % to about 10 at %, based on a total number of atoms of molybdenum (Mo) and tantalum (Ta) included in the alloy.

For example, a molybdenum-tantalum alloy may further include one or more other metal atoms and/or non-metal atoms in addition to molybdenum (Mo) and tantalum (Ta), and the additionally included metal atoms and/or non-metal atoms may be included in an amount less than molybdenum (Mo) or tantalum (Ta). For example, the molybdenum-tantalum alloy may not additionally include cobalt (Co).

For example, the molybdenum-tantalum alloy may include or be composed of molybdenum (Mo) and tantalum (Ta) as the metal atoms, and may not include additional metal atoms other than molybdenum (Mo) and tantalum (Ta).

For example, the molybdenum-tantalum alloy may be represented by Mo₁₋ₓTaₓ, where x may satisfy at least one of the following inequalities: 0<x<0.50, 0<x≤0.45, 0<x≤0.40, 0<x≤0.35, 0<x≤0.30, 0<x≤0.25, 0<x≤0.20, 0<x≤0.15, 0<x≤0.10, 0<x≤0.08, 0.02≤x<0.50, 0.02≤x≤0.45, 0.02≤x≤0.40, 0.02≤x≤0.35, 0.02≤x≤0.30, 0.02≤x≤0.25, 0.02≤x≤0.20, 0.02≤x≤0.15, 0.02≤x≤0.10, 0.02≤x≤0.08, 0.03≤x<0.50, 0.03≤x≤0.45, 0.03≤x≤0.40, 0.03≤x≤0.35, 0.03≤x≤0.30, 0.03≤x≤0.25, 0.03≤x≤0.20, 0.03≤x≤0.15, 0.03≤x≤0.10, 0.03≤x≤0.08, 0.05≤x<0.50, 0.05≤x≤0.45, 0.05≤x≤0.40, 0.05≤x≤0.35, 0.05≤x≤0.30, 0.05≤x≤0.25, 0.05≤x≤0.20, 0.05≤x≤0.15, 0.05≤x≤0.10, or 0.05≤x≤0.08. For example, x in Mo₁₋ₓTaₓ may satisfy at least one of the following inequalities: 0<x≤0.15, 0<x≤0.10, 0<x≤0.08, 0.02≤x≤0.15, 0.02≤x≤0.10, 0.02≤x≤0.08, 0.03≤x≤0.15, 0.03≤x≤0.10, 0.03≤x≤0.08, 0.05≤x≤0.15, 0.05≤x≤0.10, or 0.05≤x≤0.08.

Embodiments of the conductive wire described herein may be applied to or included in an interconnect structure.

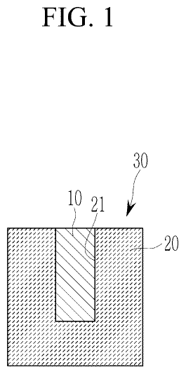

FIG. 1 is a cross-sectional view showing an interconnect structure 30 according to an embodiment.

Referring to FIG. 1, an interconnect structure 30 according to an embodiment includes a dielectric layer 20 and a conductive wire 10.

A substrate (not shown) may be disposed under the dielectric layer 20, and the substrate may be a semiconductor substrate. The semiconductor substrate may include, for example, a Group IV semiconductor material, a Group III-V semiconductor compound, or a Group II-VI semiconductor compound, for example, a Group IV semiconductor material including at least one selected from Si, Ge, Sn, and C, a Group III-V compound semiconductor material in which at least one selected from B, Ga, In, and Al are combined with at least one selected from N, P, As, or Sb, or a Group II-VI compound semiconductor material in which at least one selected from Be, Mg, Cd, and Zn are combined with at least one selected from O, S, Se, and Te. In an embodiment, for example, the semiconductor substrate may include at least one selected from Si, Ge, SiC, SiGe, SiGeC, Ge alloy, GaAs, InAs, InP, and the like, but is not limited thereto.

The substrate may include at least one semiconductor device (not shown) within and/or on the substrate, for example at least one selected from a transistor, a capacitor, a diode, and a resistor, but is not limited thereto.

The dielectric layer 20 may include, for example, at least one selected from a metal oxide, a semi-metal oxide, a carbon-doped metal oxide, a carbon-doped semi-metal oxide, a metal carbide, a semi-metal carbide, a hydrogenated metal carbide, a hydrogenated semi-metal carbide, a metal nitride, a semi-metal nitride, a carbon-doped metal nitride, a carbon-doped semi-metal nitride, a metal oxynitride, semi-a metal oxynitride, a carbon-doped metal oxynitride, a carbon-doped semi-metal oxynitride, or a combination thereof. The dielectric layer 20 may include, for example, at least one selected from AlO_{z} (0<z≤3/2, for example, Al₂O₃), AlN, ZrOₓ (0<x≤2), HfOₓ (0<x≤2), SiO₂, SiCO, SiCN, SiON, SiCOH, AlSiO, BN (Boron Nitride), or a combination thereof, but is not limited thereto.

The dielectric layer 20 may have or define one or more trenches 21.

The trench 21 may have a narrow width and may have a width of less than about 10 nm, similar to the width of the aforementioned conductive wire. A width of the trench 21 may be, for example, within the above range, less than or equal to about 9 nm, less than or equal to about 8 nm, less than or equal to about 7 nm, less than or equal to about 5 nm, greater than or equal to about 1 nm and less than about 10 nm, about 1 nm to about 9 nm, about 1 nm to about 8 nm, about 1 nm to about 7 nm, or about 1 nm to about 5 nm.

The trench 21 may have a high aspect ratio, where the aspect ratio may be a ratio of depth to width. The aspect ratio of the trench 21 may be substantially the same as the aspect ratio of the conductive wire 10, may be greater than or equal to about 3, and within the above range may be about 3 to about 50, about 3 to about 45, about 3 to about 40, about 3 to about 35, about 3 to about 30, about 5 to about 50, about 5 to about 45, about 5 to about 40, about 5 to about 35, or about 5 to about 30. The trench 21 may be narrow and deep by having a high aspect ratio within the above range.

The conductive wire 10 may be embedded in a trench 21 of the dielectric layer 20. The conductive wire 10 has a line width of less than about 10 nm as described above and may include the molybdenum-tantalum alloy. Any repetitive detailed features of the conductive wire 10 will be omitted.

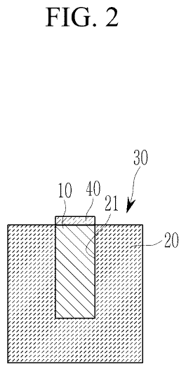

FIG. 2 is a cross-sectional view showing an interconnect structure according to another embodiment.

Referring to FIG. 2, the interconnect structure 30 according to another embodiment includes a dielectric layer 20 with a trench 21 and a conductive wire 10.

In such an embodiment, as shown in FIG. 2, the interconnect structure 30 may further include an anti-scatter layer 40 on the surface of the conductive wire 10. The anti-scatter layer 40 may more effectively reduce electron scattering on the surface of the conductive wire 10. The anti-scatter layer 40 may include a conductor, a semiconductor, and/or an insulator, and may include graphene, metal-doped graphene, or a combination thereof, but is not limited thereto.

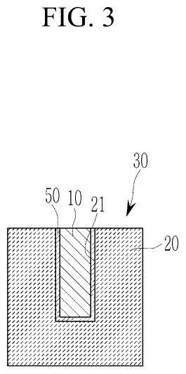

FIG. 3 is a cross-sectional view showing an interconnect structure according to another embodiment.

Referring to FIG. 3, the interconnect structure 30 according to another embodiment includes a dielectric layer 20 with a trench 21 and a conductive wire 10.

In such an embodiment, as shown in FIG. 3, the interconnect structure 30 further includes a barrier layer 50 between the conductive wire 10 and the dielectric layer 20 within the trench 21. The barrier layer 50 may effectively prevent or substantially reduce diffusion of metal atoms from the conductive wire 10 to the dielectric layer 20, thereby effectively preventing or substantially reducing an increase in resistance of the conductive wire 10 and deterioration of the interconnect structure 30. The barrier layer 50 may include a conductor, a semiconductor, and/or an insulator, such as Ti, TiN, SiN, or a combination thereof, but is not limited thereto.

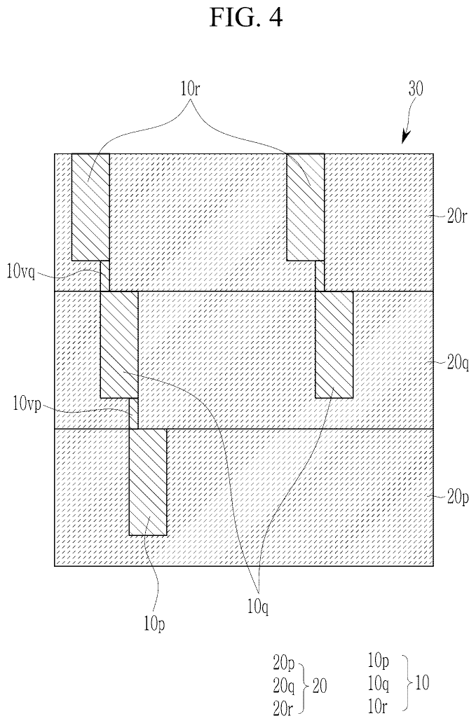

FIG. 4 is a cross-sectional view showing an interconnect structure according to another embodiment.

Referring to FIG. 4, the interconnect structure 30 according to another embodiment includes a dielectric layer 20 with a trench 21 and a conductive wire 10.

In such an embodiment, as shown in FIG. 4, the dielectric layer 20 may include a plurality of dielectric layers, e.g., first, second and third dielectric layers 20p, 20q, and 20r, disposed at different heights or levels, respectively, and the dielectric layers, e.g., the first, second and third dielectric layers 20p, 20q, and 20r, may include a same material as or different materials from each other. In an embodiment, as shown in FIG. 4, the first, second, and third dielectric layers 20p, 20q, and 20r may each have a trench, and the conductive wire 10 may be embedded in each trench.

The conductive wire 10 may include a plurality of conductive wires 10p, 10q, and 10r and vias 10vp and 10vq disposed at different heights or in different dielectric layers. That is, the conductive wire 10 may include a first conductive wire 10p, a second conductive wire 10q disposed at a different height from the first conductive wire 10p, a third conductive wire 10r disposed at a different height from the first and second conductive wires 10p and 10q, a via 10vp connecting the first conductive wire 10p and the second conductive wire 10q, and a via 10vq electrically connecting the second conductive wire 10q and the third conductive wire 10r. However, the present disclosure is not limited thereto and may further include another conductive wire disposed at a different height or in a horizontal direction from the first, second and/or third conductive wires 10p, 10q, and 10r and another via electrically connecting a plurality of conductive wires disposed at different heights.

The first, second and third conductive wires 10p, 10q, and 10r may be the same as the aforementioned conductive wire 10 and may have a line width of less than about 10 nm and include a molybdenum-tantalum alloy. Any repetitive detailed description of the conductive wire 10 will be omitted. In such an embodiment, the anti-scatter layer 40 described above with reference to FIG. 2 may be additionally formed on the surfaces of the first, second and third conductive wires 10p, 10q, and 10r. In such an embodiment, the barrier layer 50 described above with reference to FIG. 3 may be additionally formed between the first, second and third conductive wires 10p, 10q, and 10r and the dielectric layer 20p, 20q, and 20r.

The vias 10vp and 10vq may include or be made of a different conductor than the first, second, and third conductive wire 10p, 10q, and 10r, i.e., a different conductor than the aforementioned molybdenum-tantalum alloy, and may not include the molybdenum-tantalum alloy.

The aforementioned conductive wire 10 and/or interconnect structure 30 may be included in an integrated circuit device. The integrated circuit device may include dynamic random-access memory (DRAM) or logic device, but is not limited thereto. The integrated circuit device may include unit devices including, for example, a transistor, a capacitor, a diode, a resistor, or a combination thereof, which are electrically connected to the aforementioned conductive wire 10. The integrated circuit device may be applied to wire (e.g., bit lines, word lines, etc.) and/or back end of line (BEOL) structures that are connected to unit devices such as transistors.

For example, the transistor may have various structures, for example, fin field-effect transistor (FinFET), gate-all-around field-effect transistor (GAAFET), multi-bridge channel field-effect transistor (MBCFET), complementary field-effect transistor (CFET), or vertical field-effect transistor (VFET), but is not limited thereto. For example, the transistor may include a two-dimensional material as the active material and may be a CFET, an MBCFET, or a carbon nanotube field effect transistor (CNTFET), but is not limited thereto.

Embodiments of an integrated circuit device according to the present disclosure will hereinafter be described in detail.

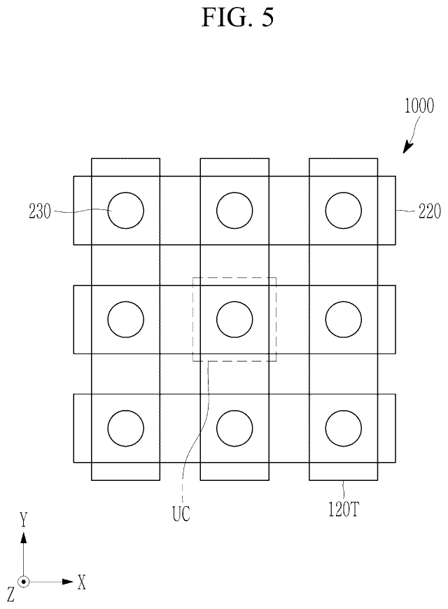

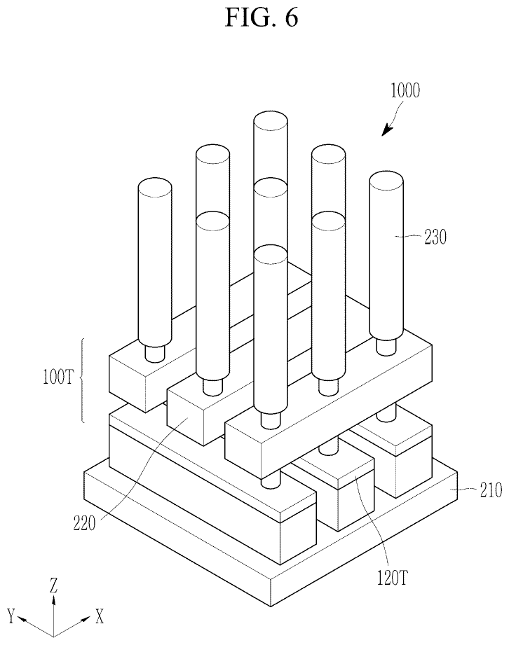

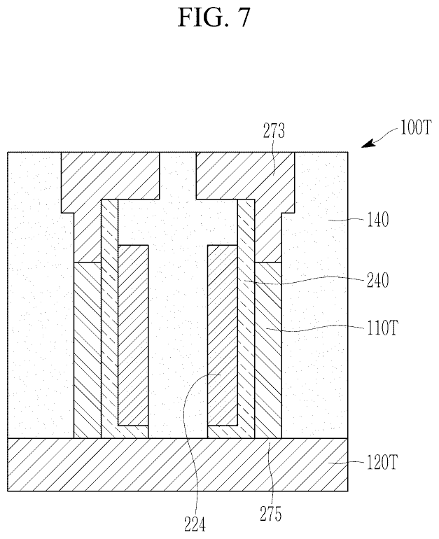

FIG. 5 is a plan view showing an integrated circuit device according to an embodiment, FIG. 6 is a perspective view showing the integrated circuit device of FIG. 5, and FIG. 7 is a schematic view showing an embodiment of a transistor of the integrated circuit device of FIG. 5.

Referring to FIGS. 5 and 6, an integrated circuit device 1000 according to an embodiment includes a plurality of active regions partitioned by a plurality of bit lines 120T and a plurality of word lines 220, and the plurality of active regions are arranged in an array form. A unit cell UC including a transistor 100T and a capacitor 230 may be disposed in each active region. The integrated circuit device 1000 according to an embodiment may be a DRAM device.

The integrated circuit device 1000 according to an embodiment includes a semiconductor substrate 210, a bit line 120T, a word line 220, a transistor 100T, and a capacitor 230.

The semiconductor substrate 210 may include a Group IV semiconductor material such as silicon (Si), germanium (Ge), silicon-germanium (SiGe), and silicon carbide (SiC); a Group III-V semiconductor material such as GaP, GaAs, and GaSb; or a combination thereof. In an embodiment, for example, the semiconductor substrate 210 may be a silicon-on-insulator (SOI) substrate or a germanium-on-insulator (GOI) substrate.

The bit line 120T and the word line 220 extend in different directions on the semiconductor substrate 210. In an embodiment, for example, the bit line 120T and the word line 220 may be arranged perpendicular to each other. The bit line 120T and the word line 220 may be disposed at different heights from the surface of the semiconductor substrate 210. In an embodiment, for example, the bit line 120T may be disposed closer to the surface of the semiconductor substrate 210 than the word line 220.

The bit line 120T and the word line 220 are each electrically connected to a transistor 100T described later. At least one selected from the bit line 120T and the word line 220 may be the conductive wire having a line width of less than about 10 nm and including a molybdenum-tantalum alloy as described above. In an embodiment, for example, each of the bit line 120T and the word line 220 may have a line width of less than about 10 nm and include a molybdenum-tantalum alloy.

The transistor 100T may be located in an active region partitioned by the bit line 120T and the word line 220 on the semiconductor substrate 210, and may be repeatedly arranged along rows and/or columns on the semiconductor substrate 210 to form a transistor array. The transistor 100T may be a vertical channel array transistor (VCAT) in which the transistor channel 110T extends perpendicular to the in-plane direction (e.g., xy direction) of the semiconductor substrate 210

Each transistor 100T may be electrically connected to the bit line 120T, the word line 220, and the capacitor 230 to perform a switching operation.

Referring to FIG. 7, a transistor 100T according to an embodiment includes a transistor channel 110T, a gate electrode 224, a gate dielectric layer 240, a source electrode 273, and a drain electrode 275. The transistor 100T may be embedded within the dielectric layer 140.

In an embodiment, the transistor channel 110T may extend perpendicular to the in-plane direction (e.g., xy direction) of the semiconductor substrate 210 on the semiconductor substrate 210. In such an embodiment, the transistor channel 110T is formed perpendicular to the in-plane direction (for example, xy direction) of the semiconductor substrate 210, so that, compared to a case having a structure in which the transistor channel 110T is formed horizontally on the semiconductor substrate 210 or a structure embedded in the semiconductor substrate 210, an area of each unit cell may be effectively reduced and thus more unit cells may be formed on the semiconductor substrate 210. Therefore, a high integration integrated circuit device 1000 may be implemented.

The gate electrode 224 may be electrically connected to the word line 220 and may extend perpendicular to the in-plane direction (e.g., xy direction) of the semiconductor substrate 210. The gate electrode 224 and the transistor channel 100T may face each other with the gate dielectric 240 interposed therebetween. The gate electrode 224 may be formed of or defined by a single layer or two or more layers.

The gate dielectric 240 may be disposed between the gate electrode 224 and the transistor channel 100T and may include a dielectric material. The gate dielectric 240 may include, for example, at least one selected from a metal oxide, a semi-metal oxide, a carbon-doped metal oxide, a carbon-doped semi-metal oxide, a metal carbide, a semi-metal carbide, a hydrogenated metal carbide, a hydrogenated semi-metal carbide, a metal nitride, a semi-metal nitride, a carbon-doped metal nitride, a carbon-doped semi-metal nitride, a metal oxynitride, a semi-metal oxynitride, a carbon-doped metal oxynitride, a carbon-doped metal oxynitride, or a combination thereof. The gate dielectric 240 may include, for example, at least one selected from AlO_{z} (0<z≤3/2, for example, Al₂O₃), AlN, ZrOₓ (0<x≤2), HfOₓ (0<x≤2), SiO₂, SiCO, SiCN, SiON, SiCOH, AlSiO, BN (Boron Nitride), or a combination thereof, but is not limited thereto.

The source electrode 273 and the drain electrode 275 may be disposed at the top and bottom of the transistor channel 100T. The source electrode 273 may be electrically connected to the capacitor 230 and the drain electrode 275 may be electrically connected to the bit line 120T. The drain electrode 275 may be a portion of the bit line 120T.

The capacitor 230 is electrically connected to the source electrode 273 of the transistor 100T and may include electrodes (not shown) facing each other and a dielectric layer (not shown) disposed therebetween. The capacitor 230 may have a cylindrical shape extending perpendicularly to an in-plane direction (e.g., xy direction) of the semiconductor substrate 210, but is not limited thereto.

An embodiment where the integrated circuit device 1000 is a DRAM device, which is an integrated circuit device, is mainly described above, but is not limited thereto and may be applied to any integrated circuit device including a conductive wire. In an embodiment, for example, integrated circuit components may be used for arithmetic operations, program execution, and/or temporary data retention.

The conductive wire 10, interconnect structure 30, and/or integrated circuit device 1000 described above may be included in various electronic devices. The electronic devices may include mobile devices, computers, laptops, tablet personal computers (PCs), smart watches, sensors, digital cameras, e-books, network devices, vehicle navigation systems, Internet of Things (IoT) devices, Internet of Everything (IoE) devices, drones, door locks, safes, automated teller machines (ATMs), security devices, medical devices, or automotive electrical components, but are not limited thereto.

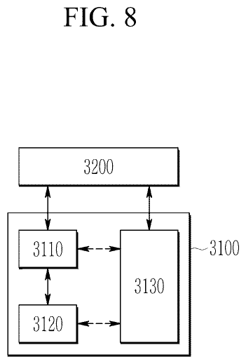

FIG. 8 is a block diagram showing an electronic device according to an embodiment.

Referring to FIG. 8, an electronic device 3100 according to an embodiment may include a memory unit 3110, an arithmetic logic unit 3120, and a control unit 3130, which may be electrically connected. In an embodiment, for example, the memory unit 3110, the arithmetic logic unit 3120, and the control unit 3130 may be implemented as a single integrated circuit device (semiconductor chip), and may be monolithically integrated on a single substrate to be implemented as a single integrated circuit device (semiconductor chip). The memory unit 3110, the arithmetic logic unit 3120, and the control unit 3130 may each independently include a transistor, a capacitor, a diode, a resistor, or a combination thereof. The electronic device 3100 may be connected to one or more input/output devices 3200.

Hereinafter, the embodiments will be described in greater detail with reference to examples. However, these examples are merely exemplary, and the scope of the invention is not limited thereto.

### [Formation of Conductive Wire]

### Example 1

A wafer is placed in the load lock chamber of the sputtering system and transferred to the main chamber of the sputtering system at a pressure of 2×10⁻⁷ Torr. Subsequently, argon gas is flowed into the main chamber at a deposition temperature of less than or equal to 750° C., the total RF power is set to 150 watts (W), and the power ratio of the molybdenum (Mo) target and the tantalum (Ta) target is adjusted to deposit a molybdenum-tantalum (Mo—Ta) alloy (Mo: 97.2 at %, Ta: 2.8 at %) on the wafer. Then, a forming gas annealing (FGA) process is performed in an argon atmosphere at the deposition temperature for 10 minutes to form molybdenum-tantalum alloy wires with line widths of 2 nm to 100 nm.

### Example 2

Molybdenum-tantalum alloy wires are formed in the same manner as in Example 1, except that the Rf power ratio of the deposition of molybdenum (Mo) and tantalum (Ta) is changed to deposit a molybdenum-tantalum alloy (Mo: 94.5 at %, Ta: 5.5 at %) instead of a molybdenum-tantalum alloy (Mo: 97.2 at %, Ta: 2.8 at %).

### Example 3

Molybdenum-tantalum alloy wires are formed in the same manner as in Example 1, except that the Rf power ratio of the deposition of molybdenum (Mo) and tantalum (Ta) is changed to deposit a molybdenum-tantalum alloy (Mo: 89.8 at %, Ta: 10.2 at %) instead of a molybdenum-tantalum alloy (Mo: 97.2 at %, Ta: 2.8 at %).

### Reference Example

Copper wires are formed in the same manner as in Example 1, except that a copper (Cu) target is used instead of a molybdenum (Mo) target and a tantalum (Ta) target.

### [Evaluation]

The resistivity of the molybdenum-tantalum alloy wires according to Examples and the copper wires according to Reference Example are evaluated.

Resistivity is calculated as the product of surface resistance and thickness (line width), where surface resistance is measured using a 4-point probe (AIT), and thickness (line width) is measured using an X-ray reflectometer (X'PERT-PRO MRD) or transmission electron microscope (TEM). It is evaluated as a relative ratio of resistivity (R) to maximum resistivity (Rₘₐₓ).

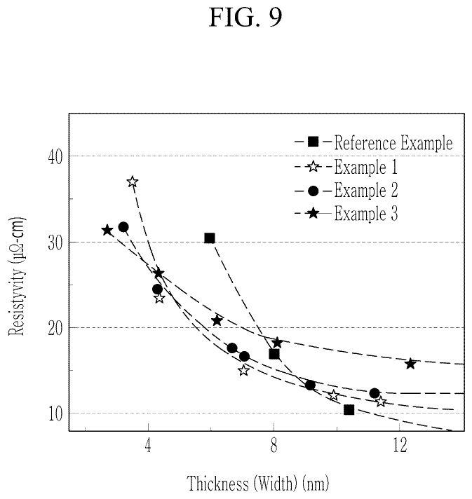

The results are shown in FIG. 9.

FIG. 9 is a graph showing the resistivity characteristics of the molybdenum-tantalum alloy wires according to Examples and the copper wires according to Reference Example.

Referring to FIG. 9, it may be seen that the copper wires according to Reference Example exhibits low resistivity at a line width of greater than or equal to about 10 nm, whereas a sharp increase in resistivity occurs at a line width of less than about 10 nm due to the material limitations of copper. On the other hand, it may be confirmed that the molybdenum-tantalum alloy wires according to Examples (i.e., Examples 1 to 3) have smaller rates of change in resistivity with decreasing line width compared to the copper wire according to Reference Example, and exhibits lower resistivity than the copper wires according to Reference Example at a line width of less than about 10 nm (e.g., about 7 nm or less).

From these, it may be expected that the molybdenum-tantalum alloy wires according to Examples may effectively prevent deterioration of electrical characteristics without a sharp increase in resistance even at a fine line width of less than about 10 nm (less than or equal to about 7 nm).

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A conductive wire comprising a molybdenum-tantalum alloy, wherein the conductive wire has a line width of less than about 10 nm.

2. The conductive wire of claim 1, wherein an aspect ratio of the conductive wire is greater than or equal to about 3.

3. The conductive wire of claim 1, wherein an amount of tantalum included in the molybdenum-tantalum alloy is less than about 50 at % based on a total number of atoms of molybdenum and tantalum.

4. The conductive wire of claim 1, wherein the molybdenum-tantalum alloy is represented by Mo₁₋ₓTaₓ (0<x≤0.15).

5. The conductive wire of claim 1, wherein a change in resistivity of the conductive wire corresponding to a 10% decrease of the line width is less than about twice.

6. The conductive wire of claim 1, wherein a resistivity of the conductive wire is less than or equal to about 40μΩ·cm.

7. An integrated circuit device comprising the conductive wire of claim 1.

8. An interconnect structure, comprising
a dielectric layer with a trench, and
a conductive wire embedded in the trench,
wherein the conductive wire comprises a molybdenum-tantalum alloy, and has a line width of less than about 10 nm.

9. The interconnect structure of claim 8, wherein an aspect ratio of the conductive wire is greater than or equal to about 3.

10. The interconnect structure of claim 8, wherein
an amount of tantalum included in the molybdenum-tantalum alloy is less than about 50 at % based on a total number of atoms of molybdenum and tantalum.

11. The interconnect structure of claim 8, wherein the molybdenum-tantalum alloy is represented by Mo₁₋ₓTaₓ (0<x≤0.15).

12. The interconnect structure of claim 8, wherein a change in resistivity of the conductive wire corresponding to a 10% decrease of the line width is less than about twice.

13. The interconnect structure of claim 8, wherein a resistivity of the conductive wire is less than or equal to about 40μΩ·cm.

14. The interconnect structure of claim 8, wherein the dielectric layer comprises at least one selected from a metal oxide, a semi-metal oxide, a carbon-doped metal oxide, a carbon-doped semi-metal oxide, a metal carbide, a semi-metal carbide, a hydrogenated metal carbide, a hydrogenated semi-metal carbide, a metal nitride, a semi-metal nitride, a carbon-doped metal nitride, a carbon-doped semi-metal nitride, a metal oxynitride, a semi-metal oxynitride, a carbon-doped metal oxynitride or a carbon-doped metal oxynitride.

15. The interconnect structure of claim 8, further comprising an anti-scatter layer on an upper portion of the conductive wire.

16. The interconnect structure of claim 8, further comprising a barrier layer between the dielectric layer and the conductive wire.

17. The interconnect structure of claim 8, wherein the dielectric layer comprises a first dielectric layer and a second dielectric layer at different heights,
a trench is defined in each of the first dielectric layer and the second dielectric layer, and
the conductive wire comprises
a first conductive wire embedded in the trench of the first dielectric layer, and
a second conductive wire embedded in the trench of the second dielectric layer.

18. The interconnect structure of claim 17, further comprising
a via electrically connecting the first conductive wire and the second conductive wire to each other, and
the via comprises a conductor other than a molybdenum-tantalum alloy.

19. An integrated circuit device comprising the interconnect structure of claim 8.

20. The integrated circuit device of claim 19, further comprising at least one selected from a transistor, a capacitor, a diode or a resistor, which are electrically connected to the conductive wire.
